(19) United States
(12) Patent Application Publication
(10) Pub. No.: US 2006/0145328 A1
(43) Pub. Date: Jul. 6, 2006

(54) Three dimensional package structure with semiconductor chip embedded in substrate and method for fabricating the same

(76) Inventor: Shih-Ping Hsu, Hsin-chu (TW)

Correspondence Address: Mr. Joseph A. Sawyer, Jr.;SAWYER LAW GROUP LLP, Embarcadero Corporate Center, Suite 406, 2465 East Bayshore Road, Palo Alto, CA, 94303, US

(21) Appl. No.: 11/270,945

(22) Filed: Nov. 10, 2005

(30) Foreign Application Priority Data
Jan. 6, 2005 (TW) 094100325

(51) Int. Cl. H01L 23/48

(52) U.S. Cl. 257/690

(57) ABSTRACT

A three dimensional package structure with semiconductor chip embedded in substrate and a method for fabricating the same are proposed. A carrier with at least one cavity is mounted on a first insulating layer, and at least one semiconductor chip is mounted on the first insulating layer and received in the cavity of the carrier. A second insulating layer is formed on the carrier and the semiconductor chip. By performing a pressing process on both of the first insulating layer and the second insulating layer, a gap between the carrier and the semiconductor chip is filled. A circuit layer may be formed on the second insulating layer and is electrically connected to the semiconductor chip. Heat dissipating vias are formed in the first insulating layer and are connected to the semiconductor chip and a heat dissipating circuit so as to facilitate dissipation of heat generated from the semiconductor chip.

### FIELD OF THE INVENTION

The present invention relates to three dimensional package structures with semiconductor chips being embedded in substrates and methods for fabricating the same, and more particularly, to a semiconductor package structure for integrating a semiconductor chip with a carrier, and a method for fabricating the semiconductor package structure.

### BACKGROUND OF THE INVENTION

Along with development of electronic industry, it has endeavored to increasingly provide electronic products with multiple functions and high performances. To satisfy the high integration and miniaturization requirements for semiconductor packages, a circuit board for accommodating a plurality of active and passive components and providing circuit connections has accordingly been developed from a one-layer board to a multi-layer board so as to increase an available circuit area on the circuit board by means of interlayer connection technology to fulfill the requirement of integrated circuits with high electronic density.

However, due to increase in the number of conductive circuit layers and the component density of the circuit board, heat generated from operation of a highly integrated semiconductor chip mounted on the circuit board is greatly increased. If the heat cannot be dissipated timely, a semiconductor packages comprising the circuit board and the semiconductor chip may become overheated, thereby adversely affecting lifetime of the semiconductor chip. At present, a ball grid array (BGA) package structure has failed to meet the requirements of electricity and heat dissipation in the case for high number of pins (over 1500 pins) and high frequency applications. A flip-chip BGA (FCBGA) package structure may be used in high pin-number and high frequency products. However, in the case of using a multi chip flip-chip package, not only the overall packaging costs are increased but also many technical limitations exist. Particularly, it is not easy to reduce the package size to become lighter, thinner and smaller and achieve high functionality as a flip chip is usually disposed at an outer surface of the package and relatively space-occupying.

Thus, there is proposed a solution to the above problem to directly embed a semiconductor chip in a substrate. As shown in FIG. 1 of a heat dissipating semiconductor package disclosed by U.S. Pat. No. 6,709,898, the semiconductor package comprises a heat spreader 102 having at least one recess 104; a semiconductor chip 114 mounted via its non-active surface in the recess 104 by an adhesive layer 120; and a circuit structure 122 formed on the heat spreader 102 and the semiconductor chip 114.

FIG. 2 is a cross-sectional view of the heat spreader 102. As shown in FIG. 2, the semiconductor chip 114 is mounted on the heat spreader 102 and received in the recess 104 that is downwardly recessed from an upper surface of the heat spreader 102 by a certain depth.

Referring to FIG. 3, a first insulating layer 126 made of such as an insulating resin is formed on the heat spreader 102 and the semiconductor chip 114 and fills a gap between the semiconductor chip 114 and the recess 104. However, since the gap is usually small, it is difficult to fill the insulating resin therein, or even voids may easily be formed in the gap during the filling process and cause a popcorn effect

during a subsequent heating process, thereby resulting in unstable quality of the entire package structure.

### SUMMARY OF THE INVENTION

In light of the above drawbacks in the conventional technology, an objective of the present invention is to provide a three dimensional package structure with semiconductor chip embedded in substrate and a method for fabricating the same, by which a semiconductor chip is embedded in a substrate and a packaging process is performed on a surface of the substrate to form the three dimensional package structure with high density and high performance.

Another objective of the present invention is to provide a three dimensional package structure with semiconductor chip embedded in substrate and a method for fabricating the same, which can uniformly control flatness of an insulating layer formed on a semiconductor chip and a carrier.

Still another objective of the present invention is to provide a three dimensional package structure with semiconductor chip embedded in substrate and a method for fabricating the same, which can improve quality of a subsequent circuit fabrication process and reliability of electrical connections.

A further objective of the present invention is to provide a three dimensional package structure with semiconductor chip embedded in substrate and a method for fabricating the same, which can improve heat dissipating efficiency of a semiconductor chip in the package structure.

In accordance with the above and other objectives, the present invention proposes a method for fabricating a three dimensional package structure with semiconductor chip embedded in substrate, comprising the steps of: mounting a carrier with at least one cavity on a first insulating layer; mounting at least one semiconductor chip on the first insulating layer and in the cavity of the carrier; forming a second insulating layer on the carrier and the semiconductor chip; and performing a pressing process on both of the first insulating layer and the second insulating layer to adhere/secure the first and second insulating layers to the carrier and allow an insulating resin of the second insulating layer to fill a gap between the cavity of the carrier and the semiconductor chip; and performing a heat-curing process to cure the first and second insulating layers. The first insulating layer and the second insulating layer can be made of a same material or different materials.

Subsequently, a plurality of vias are formed in the second insulating layer to expose electrode pads of the semiconductor chip. A circuit layer is formed on the second insulating layer. A plurality of conductive blind vias are formed in the vias of the second insulating layer, such that the circuit layer is electrically connected to the electrode pads of the semiconductor chip by the conductive blind vias.

The first insulating layer and the second insulating layer may be respectively made of a prepeg or film material such as epoxy resin, polyimide, LCP (liquid crystal polymer), BT (bismaleimide triazine), ABF (ajinomoto build-up film), PPE (polyphenylene ether), PTFE (polytetrafluoroethylene) or BCB (benzenecyclobutene). During the pressing process of the second insulating layer formed on the carrier, the gap between the semiconductor chip and the cavity of the carrier is automatically filled with the insulating resin of the second insulating layer, such that the fabrication steps and costs are reduced as compared to the conventional technology, and voids are prevented from being left in the insulating resin filled in the gap, thereby assuring quality of the entire package structure. Further during the pressing process, the insulating resin can be controlled to flow to the gap in a vacuum state but not applying pressure to the semiconductor chip, making it easy to control a position of the semiconductor chip. Moreover, the pressing process is performed in vacuum on both of the first and second insulating layers to press and flatten surfaces of the first and second insulating layers, and then the heat-curing process is carried out to cure the first and second insulating layers, thereby achieving satisfactory flatness of the first and second insulating layers and reducing the fabrication steps and costs.

After the semiconductor chip has been mounted on the first insulating layer and the second insulating layer has been formed, vias can be formed in the first insulating layer and are connected to a non-active surface of the semiconductor chip having at least one heat dissipating pad. During forming the conductive blind vias and the circuit layer in and on the second insulating layer respectively, at least one circuit layer and at least one heat dissipating via can be formed on and in the first insulating layer respectively, such that heat generated by the semiconductor chip may be dissipated out of the package structure through the heat dissipating via and the circuit layer.

A build-up process may be performed to form a multi-layer circuit build-up structure on the first and second insulating layers respectively. A plurality of conductive elements can be implanted on the circuit build-up structure and are used to electrically connect the three dimensional package structure with semiconductor chip embedded in substrate to an external device. Circuit layers of the circuit build-up structure on the first insulating layer and circuit layers of the circuit build-up structure on the second insulating layers are separated by the carrier and are electrically connected to each other by plated through holes formed in the carrier.

By the above fabrication method, a three dimensional package structure with semiconductor chip embedded in substrate according to the present invention is obtained, which comprises: a first insulating layer; a carrier having at least one cavity and mounted on the first insulating layer; at least one semiconductor chip mounted on the first insulating layer and received in the cavity of the carrier; a second insulating layer formed on the carrier and the semiconductor chip; and at least one heat dissipating via formed in the first insulating layer and connected to a non-active surface of the semiconductor chip. The package structure further comprises a circuit structure formed on the first insulating layer and comprising at least one heat dissipating circuit connected to the heat dissipating via, such that heat generated by operation of the semiconductor chip can be dissipated out of the package structure through the heat dissipating via and the heat dissipating circuit. The package structure further comprises a circuit structure formed on the second insulating layer and electrically connected to the semiconductor chip.

A circuit build-up structure can be formed on the first and second insulating layers respectively, wherein circuit layers of the circuit build-up structure on the first insulating layer and circuit layers of the circuit build-up structure on the second insulating layer are electrically connected to each other by plated through holes formed in the carrier. A plurality of conductive elements such as solder balls, pins or metal bumps can be mounted on an outer surface of the circuit build-up structure, and are used to electrically connect the three dimensional package structure with semiconductor chip embedded in substrate to an external device such as a flip-chip semiconductor component, a printed circuit board, etc.

Therefore, the package structure in the present invention is fabricated by integrating chip-packaging and circuit-forming processes and combining carrier fabrication and package fabrication, thereby avoiding drawbacks in the conventional technology. The present invention also improves heat dissipating performance of the package structure through the use of the heat dissipating via and the heat dissipating circuit. The vacuum-pressing process is performed to press the second insulating layer on the carrier embedded with the semiconductor chip, such that production yields are increased, costs are reduced, and quality and reliability of the package structure are both improved.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional view of a conventional semiconductor package disclosed in U.S. Pat. No. 6,709,898;

FIG. 2 (PRIOR ART) is a cross-sectional view showing a heat spreader receiving a semiconductor chip as disclosed in U.S. Pat. No. 6,709,898;

FIG. 3 (PRIOR ART) is a partially cross-sectional view showing a drawback caused during filling a first insulating layer in the heat spreader receiving the semiconductor chip as disclosed in U.S. Pat. No. 6,709,898;

FIGS. 4A to 4F are cross-sectional views showing steps of a method for fabricating a package structure according to a first preferred embodiment of the present invention; and

FIGS. 5A to 5H are cross-sectional views showing steps of the method for fabricating a package structure according to a second preferred embodiment of the present invention.

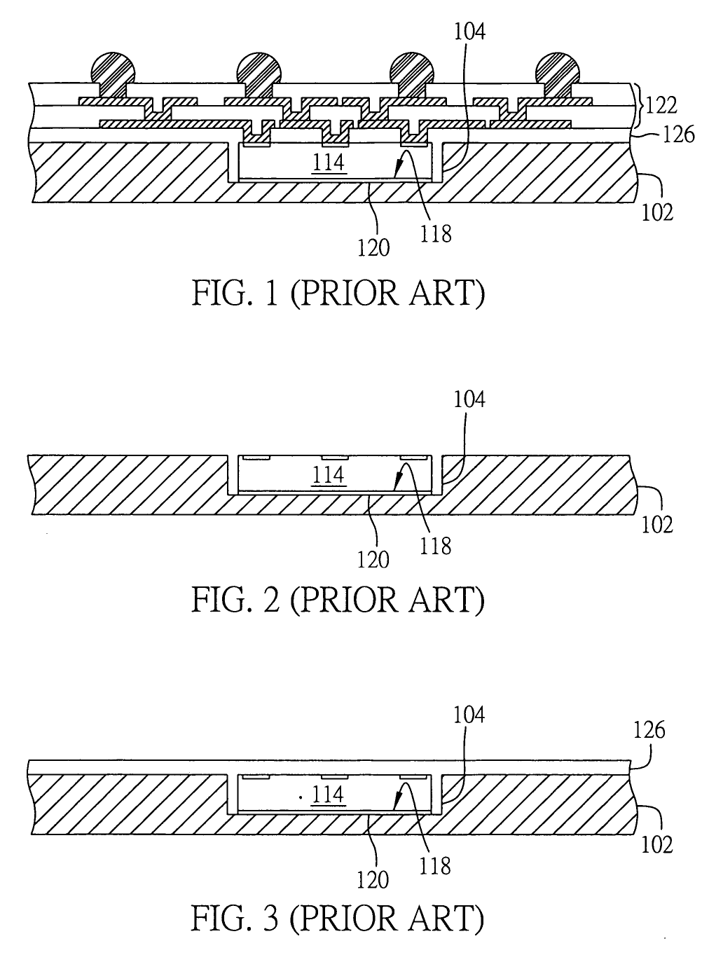

### DETAILED DESCRIPTION OF THE PREFFERED EMBODIMENTS

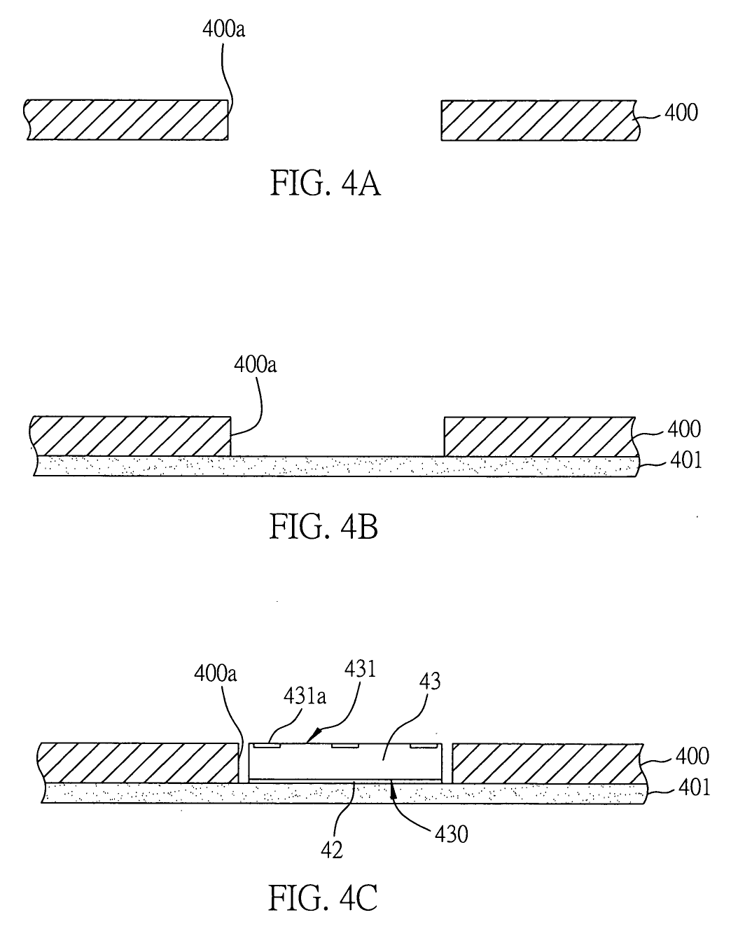

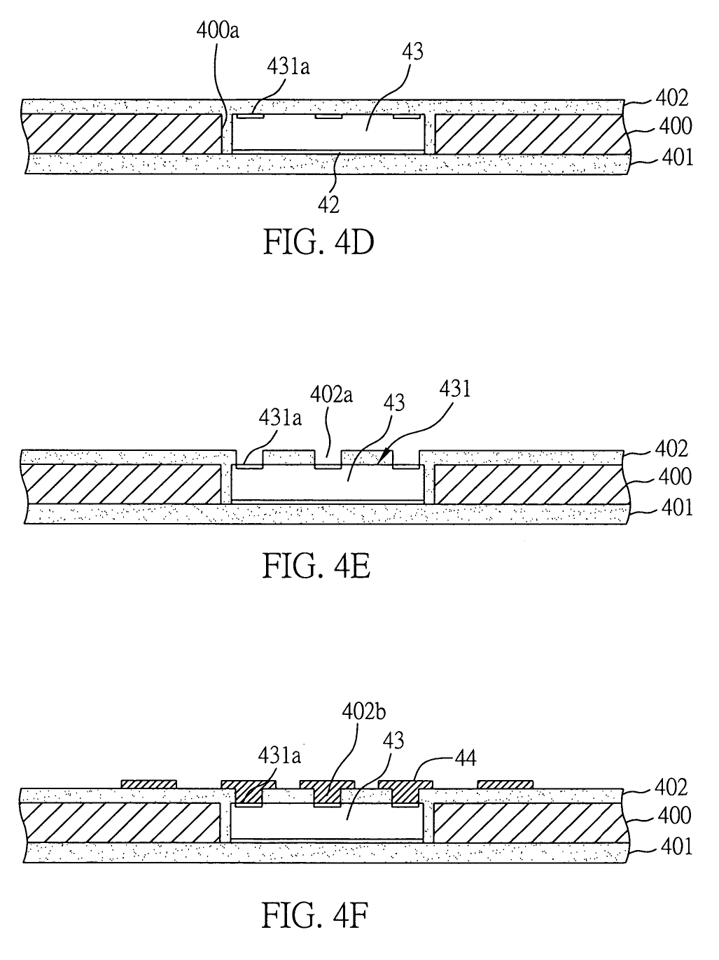

FIGS. 4A to 4F are cross-sectional views showing steps of a method for fabricating a package structure according to a first preferred embodiment of the present invention. It should be noted that all the drawings are simplified diagrams for only illustrating the basic architecture of the present invention. Thus, the drawings merely show components related to the present invention, and the shown components are not drawn according to practical numbers, shapes and size ratios. The numbers, shapes and size ratios of the components are selected according to design in practical implementation, and the component layout of the package structure may be more complex.

Referring to FIG. 4A, a carrier 400 with a cavity 400a is provided. The carrier 400 can be an insulating core plate, a metal plate, or a circuit board having circuits. A thickness of the carrier 400 may be determined according to a practical requirement.

Referring to FIG. 4B, subsequently the carrier 400 is mounted on a first insulating layer 401. The first insulating layer 401 may be made of a prepeg or film material such as epoxy resin, polyimide, LCP (liquid crystal polymer), BT (bismaleimide triazine), ABF (ajinomoto build-up film), PPE (polyphenylene ether), PTFE (polytetrafluoroethylene), BCB (benzenecyclobutene), etc.

Referring to FIG. 4C, a semiconductor chip 43 is mounted via its non-active surface 430 on the first insulating layer 401 and received in the cavity 400a of the carrier 400 by a thermally conductive adhesive layer 42. An active surface 431 of the semiconductor chip 43 has a plurality of electrode pads 431a thereon.

Referring to FIG. 4D, subsequently a second insulating layer 402 is formed on the carrier 400 and the active surface 431 of the semiconductor chip 43. The second insulating layer 402 and the first insulating layer 401 may be made of a same material or different materials. Preferably, the first insulating layer 401 is a semi-cured insulating layer, and the second insulating layer 402 is a colloid insulating layer with fluidity. Then, a pressing process such as vacuum-pressing and a heat-curing process are performed on both of the first insulating layer 401 and the second insulating layer 402 to press/adhere and cure the first and second insulating layers 401, 402, so as to obtain flat surfaces of the first and second insulating layers 401, 402 and allow a gap between the carrier 400 and the semiconductor chip 43 to be filled with an insulating resin of the second insulating layer 402.

Referring to FIG. 4E, by a laser drilling or plasma etching process, or by exposing and developing processes for a photosensitive resin, a plurality of vias 402a are formed in the second insulating layer 402 to expose the electrode pads 431a on the active surface 431 of the semiconductor chip 43.

Referring to FIG. 4F, a circuit layer 44 is formed on the second insulating layer 402, and conductive blind vias 402b are formed in the vias 402a of the second insulating layer 402 to be electrically connected to the electrode pads 431a of the semiconductor chip 43, such that the electrode pads 431a can be electrically extended outwardly through the conductive blind vias 402b and the circuit layer 44. The conductive blind vias 402b may be formed by fully or partially filling a general via conductive layer in the vias 402a of the second insulating layer 402, wherein the fully filled conductive blind vias 402b can improve electrical properties and heat dissipating efficiency of the package structure.

A circuit build-up structure (not shown) may further be formed on the first insulating layer 401 and the second insulating layer 402 respectively. Conductive elements (not shown) such as solder balls, pins or metal bumps can also be implanted on the circuit build-up structure so as to allow the semiconductor chip 43 embedded in the carrier 400 to be electrically connected to an external device. The related fabrication technology is conventional in the art and not to be further detailed herein.

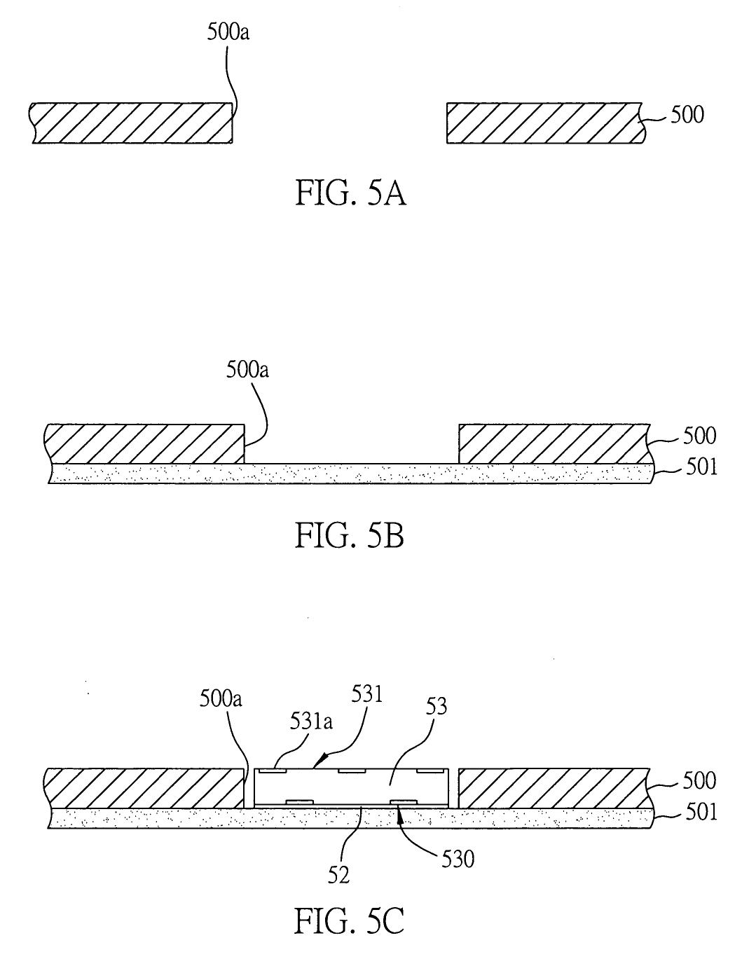

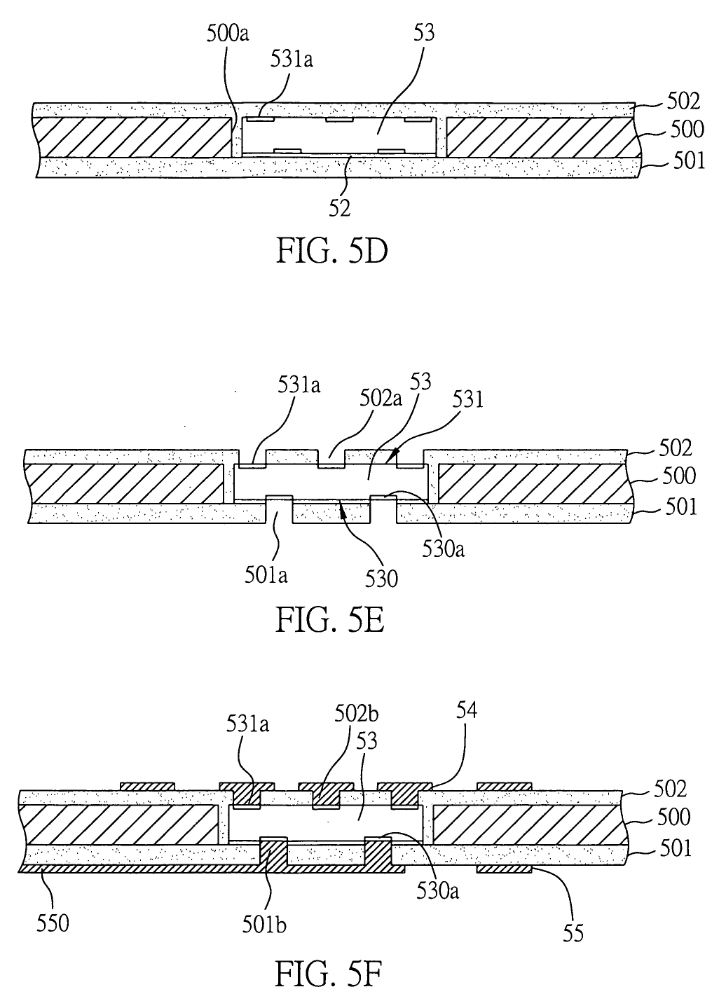

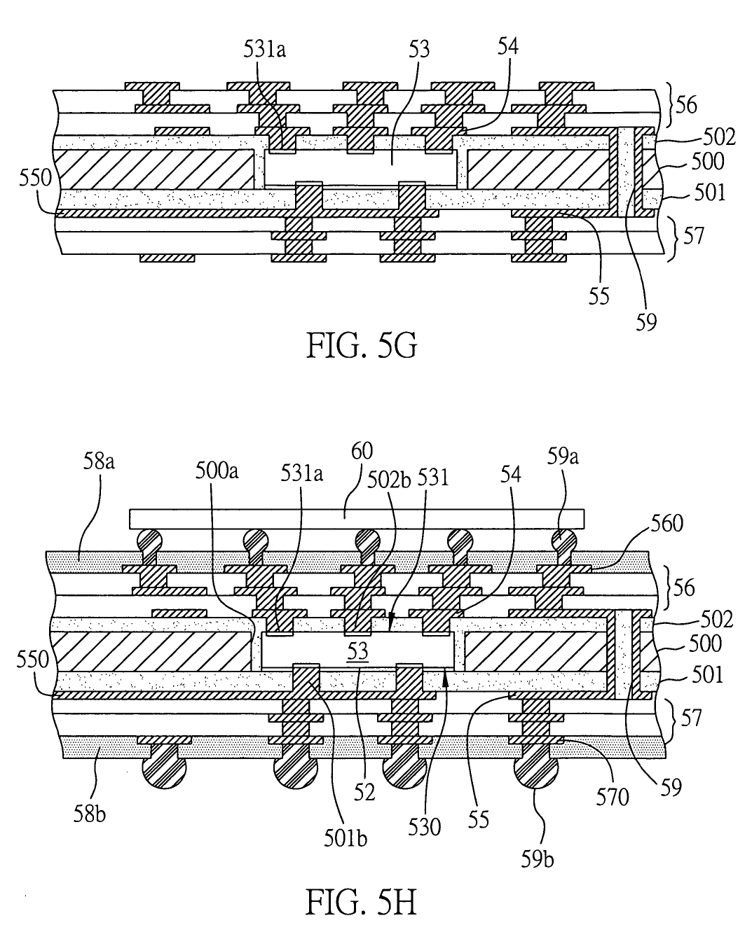

FIGS. 5A to 5H are cross-sectional views showing steps of the method for fabricating a package structure according to a second preferred embodiment of the present invention. The package structure and its fabrication method in the second embodiment are similar to those in the first embodiment, with a primary difference in that in the second embodiment, at least one heat dissipating via connected to the non-active surface of the semiconductor chip is formed in the first insulating layer, wherein the heat dissipating via is filled with a heat dissipating material, and is connected to at least one heat dissipating circuit of a circuit structure to be further connected to the outside of the package structure or further be connected directly to an external heat dissipating device to improve heat dissipating efficiency of the package structure.

Referring to FIG. 5A, a carrier 500 with a cavity 500a is provided. The carrier 500 can be an insulating core plate, a metal plate, or a circuit board having circuits. A thickness of the carrier 500 may be determined according to a practical requirement.

Referring to FIG. 5B, the carrier 500 is mounted on a first insulating layer 501. The first insulating layer 501 may be made of a prepeg or film material such as epoxy resin, polyimide, LCP (liquid crystal polymer), BT (bismaleimide triazine), ABF (ajinomoto build-up film), PPE (polyphenylene ether), PTFE (polytetrafluoroethylene), BCB (benzenecyclobutene), etc.

Referring to FIG. 5C, a semiconductor chip 53 is mounted via its non-active surface 530 on the first insulating layer 501 and received in the cavity 500a of the carrier 500 by a thermally conductive adhesive layer 52, wherein the cavity 500a is appropriately sized according to the size of the semiconductor chip 53. An active surface 531 of the chip 53 has a plurality of electrode pads 531a thereon and the non-active surface 530 of the chip 53 has a plurality of heat dissipating pads 530a thereon.

Referring to FIG. 5D, subsequently a second insulating layer 502 is formed on the carrier 500 and the active surface 531 of the semiconductor chip 53. The second insulating layer 502 and the first insulating layer 501 may be made of a same material or different materials. Then, a pressing process such as vacuum-pressing and a heat-curing process are performed on both of the first insulating layer 501 and the second insulating layer 502 so as to press/adhere and cure the first and second insulating layers 501, 502 and obtain flat surfaces of the first and second insulating layers 501, 502.

Referring to FIG. 5E, a plurality of vias 501a, 502a are respectively formed in the first insulating layer 501 and the second insulating layer 502 by a laser drilling or plasma etching process or by exposing and developing processes for a photosensitive resin. As a result, the heat dissipating pads 530a of the semiconductor chip 53 are exposed by the vias 501a of the first insulating layer 501, and the electrode pads 531a on the active surface 531 of the semiconductor chip 53 are exposed by the vias 502a of the second insulating layer 502.

Referring to FIG. 5F, a circuit layer 55 is formed on the first insulating layer 501, and a circuit layer 54 is formed on the second insulating layer 502. Heat dissipating vias 501b are formed in the vias 501a of the first insulating layer 501 by filling a heat dissipating material such as Cu in the vias 501a, and the heat dissipating vias 501b are connected to a heat dissipating circuit 550 of the circuit layer 55, such that the heat dissipating circuit 550 can be extended outwardly. Conductive blind vias 502b are formed in the vias 502a of the second insulating layer 502 such that the circuit layer 54 can be electrically connected to the electrode pads 531a of the semiconductor chip 53 by the conductive blind vias 502b. The conductive blind vias 502b may be formed by fully or partly filling a general via conductive layer in the vias 502a of the second insulating layer 502, wherein the fully filled conductive blind vias 502b can improve electrical properties and heat dissipating efficiency of the package structure.

Referring to FIG. 5G, a circuit build-up process can further be performed on the first insulating layer 501 and the circuit layer 55 and on the second insulating layer 502 and the circuit layer 54, so as to form circuit build-up structures 56, 57 respectively on two sides (e.g. upper and lower sides) of the carrier 500 receiving the semiconductor chip 53, wherein circuits respectively on the upper and lower sides of the carrier 500 are electrically connected to each other by plated through holes 59.

Referring to FIG. 5H, solder mask layers 58a, 58b are applied on outer surfaces of the circuit build-up structures 56, 57 respectively, and a plurality of openings are formed in the solder mask layers 58a, 58b to expose electrical connection pads 560, 570 on the outer surfaces of the circuit build-up structures 56, 57 respectively. A plurality of conductive elements 59a, 59b, for example solder balls, pins or metal bumps, are respectively formed on the electrical connection pads 560, 570 of the circuit build-up structures 56, 57, such that for example, an external device such as a semiconductor component 60 can be mounted on and electrically connected to the conductive elements 59a, and thus the semiconductor chip 53 embedded in the carrier 500 can be electrically connected to the external device by the conductive elements 59a.

Accordingly, as shown in FIG. 5H, the package structure obtained from the above fabrication method in the present invention includes: a first insulating layer 501; a carrier 500 having at least one cavity 500a and mounted on the first insulating layer 501; at least one semiconductor chip 53 mounted on the first insulating layer 501 and received in the cavity 500a of the carrier 500 by a thermally conductive adhesive layer 52; a second insulating layer 502 formed on the carrier 500 and an active surface 531 of the semiconductor chip 53 and filling a gap between the cavity 500a of the carrier 500 and the semiconductor chip 53 by a pressing process; and at least one circuit layer 54 formed on the second insulating layer 502, and at least one circuit layer 55 formed on the first insulating layer 501, wherein the circuit layer 54 is electrically connected to electrode pads 531a of the semiconductor chip 53 by conductive blind vias 502b formed in the second insulating layer 502, and is electrically connected to the circuit layer 55 by plated through holes 59 formed in the carrier 500. The circuit layer 55 further includes a heat dissipating circuit 550 connected to heat dissipating vias 501b formed in the first insulating layer 501, and the heat dissipating vias 501b are connected to heat dissipating pads 530a of the semiconductor chip 53. As a result, heat generated from operation of the semiconductor chip 53 can be dissipated out of the package structure through the heat dissipating pads 530a of the semiconductor chip 53, the heat dissipating vias 501b and the heat dissipating circuit 550, thereby improving heat dissipating performance of the package structure.

The package structure further includes a circuit build-up structure 56 formed on the second insulating layer 502 and the circuit layer 54. The circuit build-up structure 56 includes at least one insulating layer, a circuit layer laminated on the insulating layer, and conductive blind vias penetrating the insulating layer and electrically connected to the circuit layer. A plurality of electrical connection pads 560 are formed on the circuit layer at an outer surface of the circuit build-up structure 56, and a plurality of conductive elements 59a such as solder balls and conductive bumps can be implanted on the electrical connection pads 560, such that an external device such as a semiconductor component 60 can be mounted on the conductive elements 59a so as to allow the semiconductor chip 53 received in the carrier 500 to be electrically connected to the external device through the electrode pads 531a of the semiconductor chip 53, the conductive blind vias 502b, the circuit layer 54 and the conductive elements 59a.

A circuit build-up layer 57 is further formed on the first insulating layer 501 and the circuit layer 55, and has a structure similar to that of the circuit build-up layer 56. The circuit build-up layer 57 can be electrically connected to the circuit build-up layer 56 by plated through holes 59 formed in the carrier 500. A plurality of electrical connection pads 570 are formed on a circuit layer at an outer surface of the circuit build-up structure 57, and a plurality of conductive elements 59b such as solder balls and conductive bumps can be implanted on the electrical connection pads 570, such that an external device such as a printed circuit board (not shown) can be mounted to the conductive elements 59b, and the semiconductor chip 53 received in the carrier 500 can be electrically connected to the external device through the circuit build-up layer 57, the electrical connection pads 570 and the conductive elements 59b.

The invention has been described using exemplary preferred embodiments. However, it is to be understood that the scope of the invention is not limited to the disclosed embodiments. On the contrary, it is intended to cover various modifications and similar arrangement. The scope of the claims therefore should be accorded the broadest interpretation so as to encompass all such modifications and similar arrangements.

What is claimed is:

1. A method for fabricating a three dimensional package structure with semiconductor chip embedded in substrate, comprising the steps of:
mounting a carrier with at least one cavity on a first insulating layer;
mounting at least one semiconductor chip on the first insulating layer and in the cavity of the carrier, wherein a plurality of electrode pads are formed on a surface of the semiconductor chip;
forming a second insulating layer on the carrier and the semiconductor chip; and
performing a pressing process on both of the first insulating layer and the second insulating layer.

2. The method of claim 1, wherein the first insulating layer and the second insulating layer are made of a same material.

3. The method of claim 1, wherein the first insulating layer and the second insulating layer are made of different materials.

4. The method of claim 1, wherein the first insulating layer is a semi-cured insulating layer and the second insulating layer is a colloid insulating layer with fluidity.

5. The method of claim 1, wherein the carrier is one of an insulating core plate, a metal plate, and a circuit board having circuits.

6. The method of claim 1, further comprising:
forming vias in the second insulating layer to expose the electrode pads of the semiconductor chip; and
forming a circuit layer on the second insulating layer and forming conductive blind vias in the vias of the second insulating layer such that the circuit layer is electrically connected to the electrode pads of the semiconductor chip by the conductive blind vias.

7. The method of claim 6, further comprising performing a build-up process to form a circuit build-up structure on the second insulating layer and the circuit layer on the second insulating layer.

8. A method for fabricating a three dimensional package structure with semiconductor chip embedded in substrate, comprising the steps of:
mounting a carrier with at least one cavity on a first insulating layer;
mounting at least one semiconductor chip on the first insulating layer and in the cavity of the carrier, wherein the semiconductor chip has an active surface and a non-active surface opposed to the active surface;
forming a second insulating layer on the carrier and the semiconductor chip;
performing a pressing process on both of the first insulating layer and the second insulating layer; and
forming a circuit layer on a surface of the first insulating layer and forming at least one heat dissipating via in the first insulating layer, wherein the heat dissipating via is connected to the non-active surface of the semiconductor chip and the circuit layer.

9. The method of claim 8, wherein the first insulating layer and the second insulating layer are made of a same material.

10. The method of claim 8, wherein the first insulating layer and the second insulating layer are made of different materials.

11. The method of claim 8, wherein the first insulating layer is a semi-cured insulating layer and the second insulating layer is a colloid insulating layer with fluidity.

12. The method of claim 8, further comprising performing a build-up process to form a circuit build-up structure on the first insulating layer and the circuit layer on the first insulating layer.

13. The method of claim 8, further comprising forming a circuit layer on the second insulating layer, wherein the circuit layer is electrically connected to the active surface of the semiconductor chip.

14. The method of claim 13, wherein the circuit layer on the second insulating layer is fabricated by the steps comprising:
forming vias in the second insulating layer to expose electrode pads on the active surface of the semiconductor chip; and
forming the circuit layer on the second insulating layer and forming conductive blind vias in the vias of the second insulating layer such that the circuit layer is electrically connected to the electrode pads of the semiconductor chip by the conductive blind vias.

15. The method of claim 13, wherein the circuit layer on the second insulating layer is electrically connected to the circuit layer on the first insulating layer by plated through holes formed in the carrier.

16. The method of claim 13, further comprising performing a build-up process to form a circuit build-up structure on the second insulating layer and the circuit layer on the second insulating layer.

17. The method of claim 16, further comprising implanting a plurality of electrical connections pads, a plurality of conductive elements and a semiconductor component on an outer surface of the circuit build-up structure.

18. The method of claim 8, wherein the carrier is one of an insulating core plate, a metal plate, and a circuit board having circuits.

19. A three dimensional package structure with semiconductor chip embedded in substrate, comprising:
a first insulating layer;
a carrier having at least one cavity and mounted on the first insulating layer;
at least one semiconductor chip having an active surface and a non-active surface, wherein the semiconductor chip is mounted via the non-active surface thereof on the first insulating layer and is received in the cavity of the carrier;
a second insulating layer formed on the carrier and the semiconductor chip, and filling a gap between the cavity of the carrier and the semiconductor chip; and
a circuit layer formed on the first insulating layer, and connected to the non-active surface of the semiconductor chip by at least one heat dissipating via formed in the first insulating layer.

21. The package structure of claim 19, further comprising a circuit build-up structure formed on the first insulating layer and the circuit layer on the first insulating layer.

22. The package structure of claim 19, further comprising a circuit layer formed on the second insulating layer, and electrically connected to electrode pads on the active surface of the semiconductor chip by conductive blind vias formed in the second insulating layer.

23. The package structure of claim 21, further comprising a circuit build-up structure formed on the second insulating layer and the circuit layer on the second insulating layer.

24. The package structure of claim 22, further comprising a plurality of plated through holes formed in the carrier, for electrically connecting the circuit layer on the second insulating layer to the circuit layer on the first insulating layer.

25. The package structure of claim 22, wherein a plurality of electrical connection pads, a plurality of conductive elements and a semiconductor component are implanted on an outer surface of the circuit build-up structure.

26. The package structure of claim 19, wherein the carrier is one of an insulating core plate, a metal plate, and a circuit board having circuits.

27. The package structure of claim 19, wherein the first insulating layer and the second insulating layer are made of a same material.

28. The package structure of claim 19, wherein the first insulating layer and the second insulating layer are made of different materials.

29. The package structure of claim 19, wherein the first insulating layer is a semi-cured insulating layer and the second insulating layer is a colloid insulating layer with fluidity.
